(19) United States
(12) Patent Application Publication
(10) Pub. No.: US 2010/0163406 A1
(43) Pub. Date: Jul. 1, 2010

(54) SUBSTRATE SUPPORT IN A REACTIVE SPUTTER CHAMBER

(75) Inventors: HIEN-MINH HUU LE, San Jose, CA (US); David Tanner, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/346,778

(22) Filed: Dec. 30, 2008

(51) Int. Cl. C23C 14/34; C23C 14/00

(52) U.S. Cl. 204/192.29; 204/298.23

(57) ABSTRACT

An apparatus for sputter depositing a transparent conductive oxide (TCO) layer are provided in the present invention. The transparent conductive oxide layer may be utilized as a contact layer on a substrate or a back reflector in a photovoltaic device. In one embodiment, the apparatus includes a processing chamber having an interior processing region, a substrate carrier system disposed in the interior processing region, the substrate carrier system having a plurality of rollers for conveying a substrate through the interior processing region, and an insulating member electrically isolating the rollers from the processing chamber.

### BACKGROUND OF THE DISCLOSURE

1. Field of the Invention

The present invention relates to a reactive sputter chamber for depositing a transparent conductive film, more specifically, a reactive sputter chamber for depositing a transparent conductive film on a large transparent substrate.

2. Description of the Background Art

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with frames and connectors.

Several types of silicon films, including microcrystalline silicon film (μc-Si), amorphous silicon film (a-Si), polycrystalline silicon film (poly-Si) and the like, may be utilized to form PV devices. A transparent conductive film or a transparent conductive oxide (TCO) film may be used as a top surface electrode, often referred as back reflector, disposed on the top of the PV solar cells. Furthermore, the TCO layer may be disposed between a substrate and a photoelectric conversion unit as a contact layer. The transparent conductive oxide (TCO) film may be deposited by a CVD plasma process, a PVD plasma process, or other associated coating process. The transparent conductive oxide (TCO) film must have high optical transmittance in the visible or higher wavelength region to facilitate transmitting sunlight into the solar cells without adversely absorbing or reflecting light energy. Additionally, low contact resistance and high electrical conductivity of the transparent conductive oxide (TCO) film are desired to provide high photoelectric conversion efficiency and electricity collection. High resistivity of the TCO layer often results in low photoelectric conversion efficiency and low current generation and collection.

Therefore, there is a need for an improved method and apparatus for depositing a transparent conductive oxide film for PV cells.

### SUMMARY OF THE INVENTION

An apparatus for sputter deposition of a transparent conductive oxide (TCO) layer suitable with high transmittance for use in PV cells are provided. The apparatus may be a physical vapor processing chamber that may produce a TCO layer with low resistivity and high film density. In one embodiment, the apparatus includes a processing chamber having an interior processing region, a substrate carrier system disposed in the interior processing region, the substrate carrier system having a plurality of rollers for conveying a substrate through the interior processing region, and an insulating member electrically isolating the rollers from the processing chamber.

In another embodiment, the apparatus includes a processing chamber having an interior processing region, a substrate carrier system disposed in the interior processing region, the substrate carrier system having a plurality of rollers for conveying substrate through the interior processing region, a plurality of targets disposed on the top of the processing chamber facing the substrate carrier system, an insulating member electrically isolating the rollers from the processing chamber.

In yet another embodiment, a method of sputter depositing a transparent conductive oxide layer includes positioning a substrate on a substrate carrier system disposed in a processing chamber, sputtering source material from a target disposed in the processing chamber as the substrate advances on the substrate carrier system, and electrically floating the substrate from ground during sputtering.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber;

FIGS. 2A-2E depicts different embodiments of a substrate carrier system; and

FIG. 3 depicts a process flow of depositing a TCO layer on a substrate using the processing chamber depicted in FIG. 1.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides an apparatus of a physical vapor deposition processing chamber, e.g., a reactive sputter chamber, which may be utilized to deposit a TCO layer having low film resistivity and high film density. In one embodiment, the processing chamber may be configured to retain a substrate in an electrically floating position while sputter depositing a TCO layer on the substrate surface, preventing the substrate being grounded during deposition. Electrically floating the substrate during depositing may retain the plasma and dissociated ions on the substrate surface for a longer period of time, thereby efficiently allowing the TCO layer to be deposited on the substrate surface with high density and low film resistivity. Although the invention is described as beneficial for depositing a TCO layer, it is recognized that the apparatus and method for electrically floating a substrate positioned on a roller from a grounded surface during deposition may be beneficial for deposition of other types of film and/or film materials.

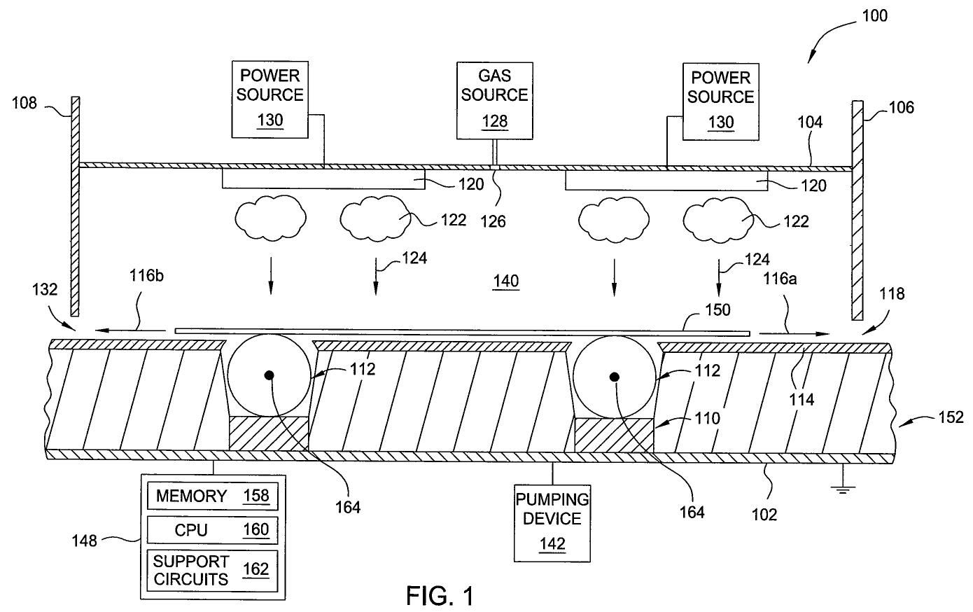

FIG. 1 illustrates an exemplary reactive sputter process chamber 100 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The processing chamber 100 includes a top wall 104, a bottom wall 102, a front wall 106 and a back wall 108, enclosing an interior processing region 140 within the process chamber 100. At least one of the walls 102, 104, 106, 108 is electrically grounded. The front wall 106 includes a front substrate transfer port 118 and the back wall 108 includes a back substrate transfer port 132 that facilitate substrate entry and exit from the processing chamber 100. The front transfer port 118 and the back transfer port 132 may be slit valves or other suitable sealable doors that can maintain vacuum within the processing chamber 100. The transfer ports 118, 132 may be coupled to a transfer chamber, load lock chamber and/or other chambers of a substrate processing system.

One or more PVD targets 120 may be mounted to the top wall 104 to provide a material source that can be sputtered from the target 120 and deposited onto the surface of the substrate 150 during a PVD process. The target 120 may be fabricated from a material utilized for deposition species. A high voltage power supply, such as a power source 130, is connected to the target 120 to facilitate sputtering materials from the target 120. In one embodiment, the target 120 may be fabricated from a material containing zinc (Zn) metal. In another embodiment, the target 120 may be fabricated from materials including metallic zinc (Zn), zinc alloy, zinc oxide and the like. Different dopant materials, such as boron containing materials, titanium containing materials, tantalum containing materials, tungsten containing materials, aluminum containing materials, and the like, may be doped into a zinc containing base material to form a target with a desired dopant concentration. In one embodiment, the dopant materials may include one or more of boron containing materials, titanium containing materials, tantalum containing materials, aluminum containing materials, tungsten containing materials, alloys thereof, combinations thereof and the like. In one embodiment, the target 120 may be fabricated from a zinc oxide material having dopants, such as, titanium oxide, tantalum oxide, tungsten oxide, aluminum oxide, aluminum metal, boron oxide and the like, doped therein. In one embodiment, the dopant concentration in the zinc containing material comprising the target 120 is controlled to less than about 10 percent by weight.

In one embodiment, the target 120 is fabricated from a zinc and aluminum alloy having a desired ratio of zinc element to aluminum element. The aluminum elements comprising the target 120 assists maintaining the target conductivity within a desired range so as to efficiently enable a uniform sputter process across the target surface. The aluminum elements in the target 120 is also believed to increase film transmittance when sputtered off and deposited onto the substrate 150. In one embodiment, the concentration of the aluminum element comprising the zinc target 120 is controlled to less than about 5 percent by weight. In embodiments wherein the target 120 is fabricated from ZnO and Al₂O₃ alloy, the Al₂O₃ dopant concentration in the ZnO base target material is controlled to less than about 2 percent by weight, such as less than 0.5 percent by weight, for example, about 0.25 percent by weight.

Optionally, a magnetron assembly (not shown) may be optionally mounted above the target 120 which enhances efficient sputtering materials from the target 120 during processing. Examples of the magnetron assembly include a linear magnetron, a serpentine magnetron, a spiral magnetron, a double-digitated magnetron, a rectangularized spiral magnetron, among others.

A gas source 128 supplies process gases into the processing volume 140 through a gas supply inlet 126 formed through the top wall 104 and/or other wall of the chamber 100. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), H₂, NO₂, N₂O and H₂O among others. It is noted that the location, number and distribution of the gas source 128 and the gas supply inlet 126 may be varied and selected according to different designs and configurations of the specific processing chamber 100.

A pumping device 142 is coupled to the process volume 140 to evacuate and control the pressure therein. In one embodiment, the pressure level of the interior processing region 140 of the process chamber 100 may be maintained at about 1 Torr or less. In another embodiment, the pressure level within the process chamber 100 may be maintained at about 10⁻³ Torr or less. In yet another embodiment, the pressure level within the process chamber 100 may be maintained at about 10⁻⁵ Torr to about 10⁻⁷ Torr. In another embodiment, the pressure level of the process chamber 100 may be maintained at about 10⁻⁷ Torr or less.

A substrate carrier system 152 is disposed in the interior processing region 140 to carry and convey a plurality of substrates 150 disposed in the processing chamber 100. In one embodiment, the substrate carrier system 152 is disposed on the bottom wall 102 of the chamber 100. The substrate carrier system 152 includes a plurality of cover panels 114 disposed among a plurality of rollers 112. The rollers 112 may be positioned in a spaced-apart relationship. The rollers 112 may be actuated by actuating device (not shown) to rotate the rollers 112 about an axis 160 fixedly disposed in the processing chamber 100. The rollers 112 may be rotated clockwise or counter-clockwise to advance (a forward direction shown by arrow 116a) or backward (a backward direction shown by arrow 116b) the substrates 150 disposed thereon. As the rollers 112 rotate, the substrate 150 is advanced over the cover panels 114. In one embodiment, the rollers 112 may be fabricated from a metallic material, such as Al, Cu, stainless steel, or metallic alloys, among others.

A top portion of the rollers 112 is exposed to the processing region 140 between the cover panels 114, thus defining a substrate support plane that supports the substrate 150 above the cover panels 114. During processing, the substrates 150 enter the processing chamber 100 through the back access port 132. One or more of the rollers 112 are actuated to rotate, thereby advancing the substrate 150 across the rollers 112 in the forward direction 116a through the processing region 140 for deposition. As the substrate 150 advances, the material sputtered from the target 120 falls down and deposits on the substrate 150 to form a TCO layer with desired film properties. As the substrate 150 continues to advance, the materials sputtered from different targets 120 are consecutively deposited on the substrate surface, thereby forming a desired layer of TCO film on the substrate surface.

In order to deposit the TCO layer on the substrate 150 with high quality, an insulating member 110 electrically isolates the rollers 112 from ground. The insulating member 110 supports the rollers 112 while interrupting the electrical path between the rollers 112 and a grounded surface, such as the processing chamber 100. As the rollers 112 are insulated from ground, the substrate 150 supported thereon is maintained in an electrically floating position, thereby assisting accumulating ions, charges, and species from the plasma on the substrate surface. The accumulation of the ions and plasma on the substrate surface helps retain reactive species on the substrate surface and allows the active species to have sufficient time to pack atoms on the substrate surface, thereby improving the quality of the deposited TCO layer, such as providing high film density. Accordingly, unwanted defects, such as voids or irregular atoms/grain arrangement may be reduced and/or eliminated, thereby providing a TCO layer having desirable high film density and low film resistivity.

In one embodiment, the insulating mechanism 110 may be in form of an insulating pad fabricated from an insulating material, such as rubber, glass, polymer, plastic, and polyphenylene sulfide (PPS), polyetheretherketone (PEEK) or any other suitable insulating materials that can provide insulation to the rollers to the bottom wall 102 of the processing chamber 100. In one embodiment, the insulating pad 110 is a non-conductive material, such as polyphenylene sulfide (PPS), polyetheretherketone (PEEK), or the like.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, as the substrate 150 is advanced by the roller 112, the material is sputtered from the target 120 and deposited on the surface of the substrate 150. The target 120 is biased by the power source 130 to maintain a plasma 122 formed from the process gases supplied by the gas source 128 and biased toward the substrate surface (as shown by arrows 124). The ions from the plasma are accelerated toward and strike the target 120, causing target material to be dislodged from the target 120. The dislodged target material and process gases form a layer on the substrate 114 with a desired composition.

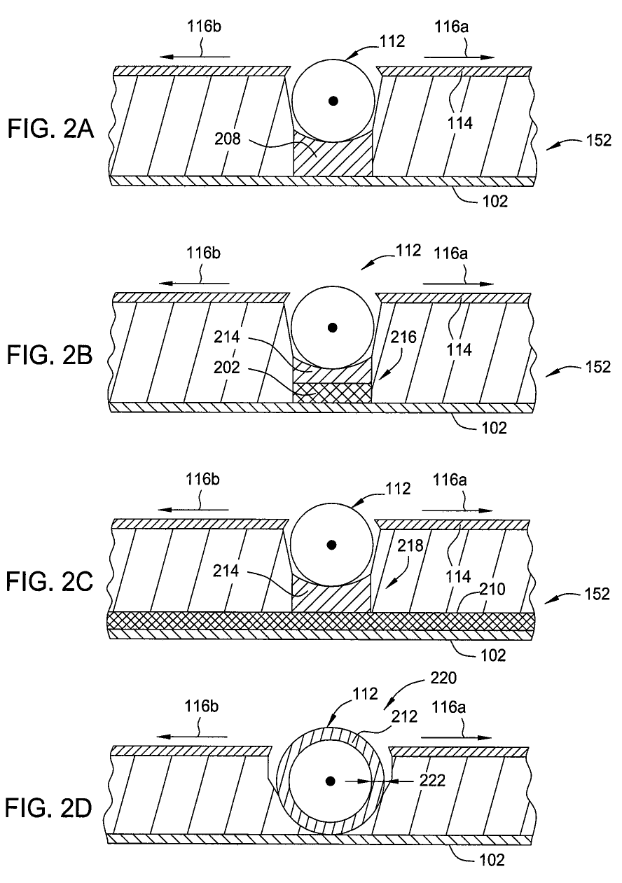

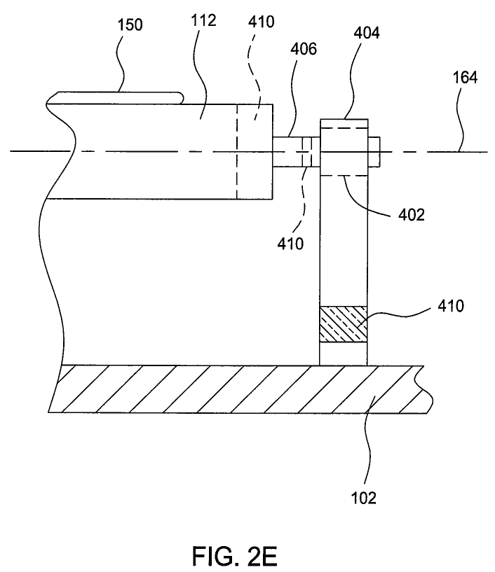

FIGS. 2A-E depicts different embodiments of the insulating member 110 that may be utilized to electrically float the substrate 150 from ground. FIG. 2A depicts an insulating member 110 in form of an insulating support 208 utilized to support the roller 112 above the bottom wall 102 in the substrate carrier system 152. The insulating support 208 electrically insulates the rollers 112 from the bottom wall 102 of the chamber so that the substrate supported on the roller 112 is maintained electrically floating from the chamber bottom wall 102 and ground. The insulating support 208 may be fabricated from a similar material as described to fabricate insulating member 110 depicted in FIG. 1. In one embodiment, the insulating support 208 may be fabricated from a non-conductive material, such as polyphenylene sulfide (PPS), polyetheretherketone (PEEK), or the like.

FIG. 2B depicts another embodiment of insulating member 110 in the form of an insulating support 216 that may be utilized to support the roller 112. The insulating support 216 includes an upper support 214 mounted on a lower insulating pad 202. The material selected to fabricate the upper support 214 may be a metallic material or other material selected to reduce contact friction with the rollers 112. In one embodiment, the upper support 214 may be fabricated from Al, Cu, stainless steel, alloys thereof, and other suitable metallic materials or metallic alloys. The lower insulating pad 202 may be fabricated from an insulating material, similar to the insulating member 110 described with reference to FIG. 1.

FIG. 2C depicts another embodiment of insulating member 110 in the form of an insulating support 218. Similar to the insulating support 216 depicted in FIG. 2B, the insulating support 218 includes the upper support 214 and a lower insulating pad 210. The upper support 214 may be a friction reducing material. The lower insulating pad 210 is a continuous pad mounted on the upper surface of the bottom wall 102 of the processing chamber. The insulating pad 210 may provide insulation of the upper support 214 along the entire surface of the bottom wall 210. As discussed above, the lower continuous insulating pad 210 may be fabricated from an insulating material, such as described above.

FIG. 2D depicts another embodiment of insulating member 110 in the form of an insulting spacer 220 that may be utilized to keep the substrate electrically floating. Instead of utilizing an insulating pad, insulating support, or insulating materials disposed between the roller 112 and the bottom wall 102, the spacer 220 may be a coating layer 212 disposed around an outer surface of the roller 212 that insulates the substrate 150 from the rollers 112. The coating layer 212 may have a suitable thickness 222 sufficient to provide good electrical insulation between the rollers 112 and the substrate 150. In one embodiment, the coating layer 212 may have a thickness 222 between about 0 mm and about 20 mm, such as between about 5 mm and about 15 mm. The material utilized to fabricate the coating layer 212 is similar to the insulating member 110. Alternatively, the insulating spacer 220 may be in the form of a plurality of insulating sheets disposed on each roller 112.

FIG. 2E depicts yet another embodiment of insulating member 110 in the form of an insulating member 410 that may be utilized to keep the substrate electrically floating. In the embodiment of FIG. 2E, the roller 112 supporting the substrate 150 has a shaft 406 extending therefrom on which the roller 112 rotates. The shaft 406 interfaces with a bearing 402 mounted in a bearing support 404. The bearing support 404 is coupled to the chamber bottom wall 102 and supports the roller 112 at a predetermined distance above the chamber bottom wall 102. The roller 112 is electrically isolated from the bottom wall 102 by the insulting member 410. The insulting member 410 may have a suitable thickness sufficient to provide an electrically open circuit between the bottom wall 102 and the substrate 150 through the roller 112. In one embodiment, the material utilized to fabricate the insulting member 410 is as described for the insulating member 110. In one embodiment, the insulting member 410 is part of the bearing support 404, roller 112 or shaft 406, thereby interrupting the electrical path therethrough. In another embodiment, the insulting member 410 is positioned between the bearing support 404 and the chamber bottom wall 102. In another embodiment, the insulting member 410 is part of the bearing 402 disposed between the bearing support 404 and the shaft 406. In another embodiment, the insulting member 410 is disposed between the roller 112 and the shaft 406. In still another embodiment, the insulting member 410 comprises the entire bearing support 404, the entire roller 112, the entire shaft 406 or combination thereof.

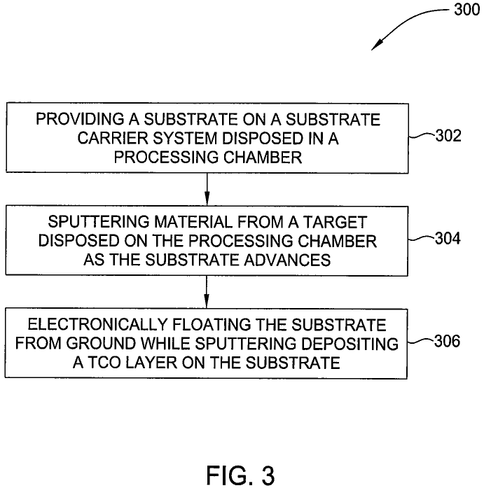

FIG. 3 depicts a process 300 of depositing a TCO layer on a substrate in a reactive sputter chamber, such as the reactive sputter processing chamber 100 depicted in FIG. 1. The process 300 begins at step 302 by providing a substrate on a substrate carrier system disposed in a processing chamber. In the embodiment wherein the processing chamber 100 of FIG. 1 is utilized, the substrate 150 is positioned on the substrate carrier system 152 disposed in the processing chamber 100 for depositing a TCO layer on the substrate 150.

At step 304, a RF or a DC power is supplied to the target 120 to dislodge materials from the target 120 to deposit on the substrate surface. As discussed above, while sputtering, the roller 112 rotates to actuate the substrate 150 disposed thereon to advance forward. As the substrate 150 advances on the substrate carrier system 152, the substrates 150 passes the plurality of targets 120 disposed on the top wall 104 of the processing chamber and receives the dislodged materials from the target 120, thereby depositing a TCO layer on the substrate surface.

At step 306, while sputter depositing, the substrate 150 is kept electrically floating on the substrate carrier system 152, e.g., insulated from ground, during processing. As the insulating member 110 interrupts the electrical path between the rollers 112 and the bottom wall 102 of the processing chamber 100, the insulating member 110 efficiently keeps the substrate 150 from being grounded during processing. As the substrate 150 is electrically floating and isolated from ground while processing, the ions and charges generated from plasma 124 may be retained on the substrate surface for a longer period of time instead of being drawn to ground, so that the ions, atoms and charges may have sufficient time to be built, packed and gradually piled up on the substrate surface, thereby forming a TCO layer having a higher film density. Higher film density of a TCO layer may also provide a lower film resistivity. Accordingly, by electrically floating the substrate during deposition, better film properties may be obtained, thereby improving the electrical performance of the film layer which is particularly beneficial for TCO layers utilized for solar cell applications.

Thus, methods and apparatus for sputtering depositing a TCO layer with high film density and low film resistivity are provided. The methods and apparatus advantageously provide an insulation member between a substrate and a substrate carrier system so the substrate remains in electrically floating from ground. As a result, TCO films having higher density film and low defects may be obtained. In this manner, the resultant TCO layer may have a low film resistivity, which efficiently increases the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. An apparatus for depositing a transparent conductive oxide layer, comprising:
a processing chamber having an interior processing region;
a substrate carrier system disposed in the interior processing region, the substrate carrier system having a plurality of rollers for conveying a substrate through the interior processing region; and
an insulating member electrically isolating the rollers from the processing chamber.

2. The apparatus of claim 1, further comprising:
a plurality of PVD targets disposed in the interior processing region.

3. The apparatus of claim 1, wherein the insulating member further comprises:
an insulating support configured to support and insulate the roller from ground.

4. The apparatus of claim 1, wherein the insulating member further comprises:
an insulating pad disposed on a bottom wall of the processing chamber.

5. The apparatus of claim 1, wherein the insulating member further comprises:
an upper roller support disposed on a lower insulating pad.

6. The apparatus of claim 5 wherein the upper support is fabricated from a metallic material selected from a group consisting of aluminum, copper stainless steel, or metallic alloys.

7. The apparatus of claim 5, wherein the lower insulating pad is fabricated from an insulating material selected from a group consisting of glass, plastic, polymer, polyphenylene sulfide (PPS), or polyetheretherketone (PEEK).

8. The apparatus of claim 2, wherein the target has dopants doped into a base material, wherein the base material is a zinc oxide containing material and the dopants are selected from a group consisting of boron containing materials, titanium containing materials, tantalum containing materials, aluminum containing materials, tungsten containing materials, alloys thereof, or combinations thereof.

9. The apparatus of claim 3, wherein the insulating support is fabricated from an insulating material selected from a group consisting of glass, plastic, polymer, polyphenylene sulfide (PPS), or polyetheretherketone (PEEK).

10. The apparatus of claim 1, wherein the insulating member further comprises:
a coating layer disposed on an outer surface of the roller.

11. An apparatus for depositing a transparent conductive oxide layer, comprising:
a processing chamber having an interior processing region and two substrate transfer ports;
a substrate carrier system disposed in the interior processing region, the substrate carrier system having a plurality of rollers for conveying substrate between the transfer ports through the interior processing region;
a plurality of PVD targets disposed in the processing chamber and facing the substrate carrier system; and
an insulating member electrically isolating the rollers from the processing chamber.

12. The apparatus of claim 11, wherein the target has dopants doped into a base material, wherein the base material is a zinc oxide containing material and the dopants are selected from a group consisting of boron containing materials, titanium containing materials, tantalum containing materials, aluminum containing materials, tungsten containing materials, alloys thereof, or combinations thereof.

13. The apparatus of claim 11, wherein the insulating member further comprises:
an insulating pad or support disposed on a bottom wall of the processing chamber, wherein the insulating pad or support is fabricated from an insulating material selected from a group consisting of glass, plastic, polymer, polyphenylene sulfide (PPS), or polyetheretherketone (PEEK).

14. The apparatus of claim 11 further comprising:
a bearing support coupled to the processing chamber and supporting the roller in a predefined position, wherein the insulating member substantially prevents electrical current from flowing through the bearing support to the processing chamber.

15. The apparatus of claim 14, wherein the insulating member is part or all of at least of a bearing is support coupled to the processing chamber and supporting the roller in a predefined position, a shaft on which the roller rotates or the roller.

16. A method of sputter depositing a transparent conductive oxide layer, comprising:
positioning a substrate on a substrate carrier system disposed in a processing chamber;
sputtering source material from a target disposed in the processing chamber as the substrate advances on the substrate carrier system; and
electrically floating the substrate from ground during sputtering.

17. The method of claim 16, further comprising:
depositing the sputtered material to form a TCO layer on the substrate.

18. The method of claim 16, wherein positioning the substrate further comprises:
advancing the substrate on a plurality of rollers of the substrate carrier system.

19. The method of claim 18, wherein electrically floating the substrate further comprises:
Interrupting an electrical path between the rollers and ground by an insulating member disposed between the rollers and the processing chamber.

20. The method of claim 19, wherein the insulating member is fabricated from an insulating material selected from a group consisting of glass, plastic, polymer, polyphenylene sulfide (PPS), or polyetheretherketone (PEEK).
